(19) United States
(12) Patent Application Publication
(10) Pub. No.: US 2019/0096702 A1
(43) Pub. Date: Mar. 28, 2019

(54) SUBSTRATE PROCESSING APPARATUS, SUBSTRATE PROCESSING METHOD, AND COMPUTER STORAGE MEDIUM

(71) Applicant: TOKYO ELECTRON LIMITED, Tokyo (JP)

(72) Inventors: Toshimitsu SAKAI, Yamanashi (JP); Sakae YAMASHITA, Yamanashi (JP); Keiichi NAGAKUBO, Yamanashi (JP); Yoshiaki SASAKI, Yamanashi (JP)

(21) Appl. No.: 16/144,552

(22) Filed: Sep. 27, 2018

(30) Foreign Application Priority Data
Sep. 27, 2017 (JP) 2017-185921

(51) Int. Cl. H01L 21/67; C23C 16/455; H01J 37/32

(52) U.S. Cl. CPC H01L 21/6719; H01L 21/67207; H01L 21/67201; H01J 37/3244; H01L 21/67017; C23C 16/45557; C23C 16/45519; H01L 21/67196

(57) ABSTRACT

A substrate processing apparatus includes a processing chamber in which a substrate is processed in a depressurized atmosphere and a transfer chamber connected to the processing chamber through a gate. A first gas supply unit is configured to supply an inert gas into the transfer chamber. A second gas supply unit is configured to supply an inert gas to the gate. A gas exhaust unit is configured to exhaust an atmosphere in the transfer chamber.

### CROSS-REFERENCE TO RELATED APPLICATIONS

This application claims priority to Japanese Patent Application No. 2017-185921 filed on Sep. 27, 2017, the entire contents of which are incorporated herein by reference.

### FIELD OF THE INVENTION

The present disclosure relates to a substrate processing apparatus including a processing chamber for processing a substrate in a depressurized atmosphere and a transfer chamber connected to the processing chamber through a gate, a substrate processing method using the substrate processing apparatus, and a computer storage medium.

### BACKGROUND OF THE INVENTION

For example, in a semiconductor device manufacturing process, various steps of performing predetermined processing on a semiconductor wafer (hereinafter, referred to as “wafer”) are executed in a state where a processing chamber accommodating the wafer is set to a depressurized state. These steps are executed by using, e.g., a substrate processing apparatus in which a plurality of processing chambers is arranged around a common transfer chamber. By processing a plurality of wafers at the same time in the plurality of processing chambers, the efficiency of the substrate processing is improved.

In this substrate processing apparatus, in the case of loading/unloading the wafer into/from the processing chamber, a gate (gate valve) for separating the processing chamber and the transfer chamber is opened and the wafer is transferred by a transfer arm provided in the transfer chamber. When the processing chamber and the transfer chamber communicate with each other, an atmosphere in the processing chamber flows into the transfer chamber, and the inside of the transfer chamber may be contaminated by contaminants of organic dusts (hereinafter, may be referred to as “contaminants”), particles and the like. A source of contaminants or particles in the transfer chamber is not limited to the processing chamber. The contaminants, the particles and the like may be generated in the transfer chamber due to various causes.

Therefore, Japanese Patent No. 4414869 proposes a processing apparatus including an inert gas supply line for supplying an inert gas into a transfer chamber and a gas exhaust line for exhausting the transfer chamber. In that case, an atmosphere in the transfer chamber is maintained in a clean state by constantly supplying the inert gas into the transfer chamber during the processing of the wafer in the processing chamber.

As described above, in the substrate processing apparatus, various processes are performed on the wafer. For example, COR (Chemical Oxide Removal) processing and PHT (Post Heat Treatment) processing are performed on the wafer. In the COR processing, a processing gas is made to react with a film formed on the wafer, thereby generating reaction products. In that case, when the wafer is loaded into and unloaded from the processing chamber in which the COR processing is performed by a transfer arm, organic products (hereinafter, may be referred to as “deposits”) may be adhered to the wafer or the transfer arm. Particularly, since the COR processing is performed in a depressurized atmosphere, the wafer and the transfer arm are cooled and the deposits are easily adhered thereto.

However, it is difficult to reduce the deposits adhered to the wafer or the transfer only by supplying an inert gas into the transfer chamber by the method disclosed in Japanese Patent No. 4414869.

### SUMMARY OF THE INVENTION

In view of the above, the present disclosure provides a substrate processing apparatus, which includes a processing chamber for processing a substrate in a depressurized atmosphere and a transfer chamber, capable of reducing foreign materials (deposits) introduced into the transfer chamber from the processing chamber.

In accordance with an aspect, there is provided a substrate processing apparatus including: a processing chamber in which a substrate is processed in a depressurized atmosphere; a transfer chamber connected to the processing chamber through a gate; a first gas supply unit configured to supply an inert gas into the transfer chamber; a second gas supply unit configured to supply an inert gas to the gate; and a gas exhaust unit configured to exhaust an atmosphere in the transfer chamber.

In accordance with another aspect, there is provided a substrate processing method using a substrate processing apparatus including a processing chamber in which a substrate is processed in a depressurized atmosphere and a transfer chamber connected to the processing chamber through a gate, the method including: supplying an inert gas from a first gas supply unit into the transfer chamber during the processing of the substrate in the processing chamber and transfer of the substrate between the processing chamber and the transfer chamber, and supplying an inert gas from a second gas supply unit to the gate when the gate is opened to transfer the substrate between the processing chamber and the transfer chamber.

### BRIEF DESCRIPTION OF THE DRAWINGS

The objects and features of the present disclosure will become apparent from the following description of embodiments, given in conjunction with the accompanying drawings, in which:

FIG. 1 is a plan view schematically showing a configuration of a substrate processing apparatus according to an embodiment;

FIGS. 2A and 2B explain a configuration of transfer arms, wherein FIG. 2A is a perspective view showing the entire transfer arms, and FIG. 2B is a side view of a pick unit of the transfer arm;

FIG. 3 is an explanatory view schematically showing a configuration of a gas supply unit and a gas exhaust unit provided in a transfer module;

FIG. 4 explains flow of an inert gas in the transfer module;

FIG. 5 explains flow of the inert gas at a gate;

FIG. 6 is an explanatory view schematically showing a configuration of a gas supply unit and a gas exhaust unit provided in a transfer module according to another embodiment; and

FIG. 7 explains flow of an inert gas in the transfer module according to another embodiment.

### DETAILED DESCRIPTION OF THE EMBODIMENTS

Hereinafter, embodiments will be described in detail with reference to the accompanying drawings. Like reference numerals will be given to substantially like parts throughout this specification and the drawings, and redundant description thereof will be omitted.

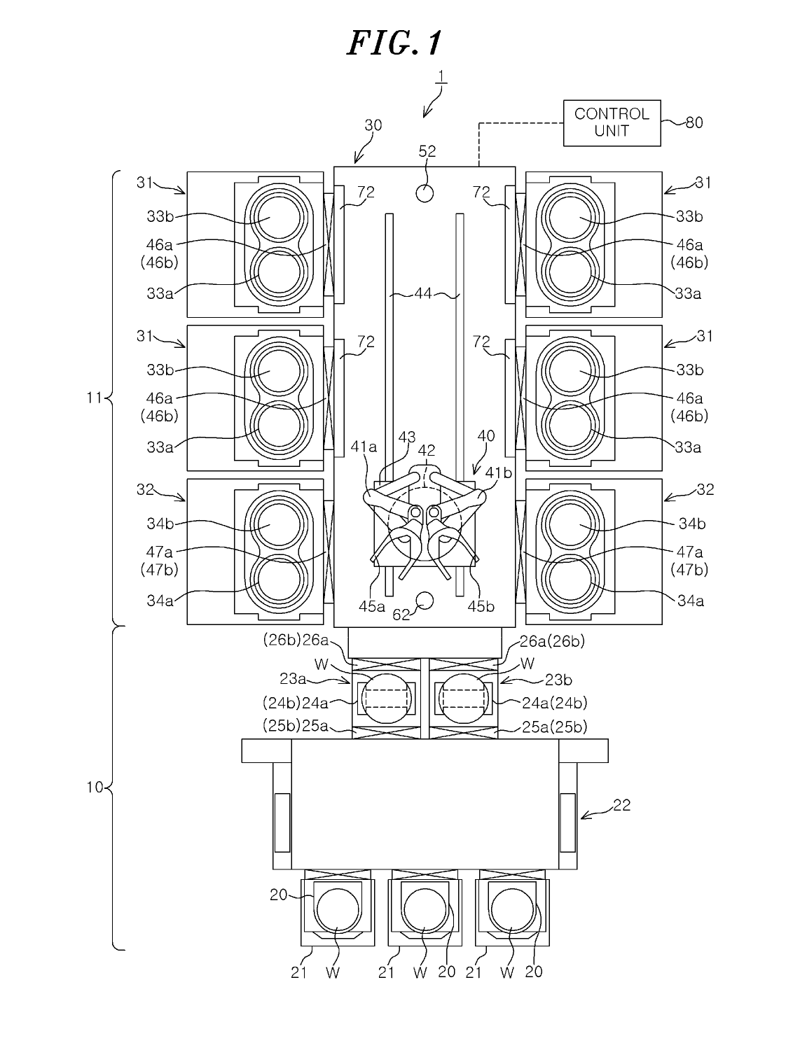

First, a configuration of a substrate processing apparatus of the present embodiment will be described. FIG. 1 is a plan view schematically showing a configuration of a substrate processing apparatus 1 of the present embodiment. In the present embodiment, a case of performing COR processing and PHT processing on a wafer W as a substrate in the substrate processing apparatus 1 will be described.

As shown in FIG. 1, the substrate processing apparatus 1 has a configuration in which a wafer storage unit 10 for storing a plurality of wafers W and a wafer processing unit 11 for performing predetermined processing on the wafers W are connected as one unit.

The wafer storage unit 10 includes: a load port 21 as a mounting place of a FOUP 20 that is a container for storing a plurality of wafers W; a loader module 22 for receiving a stored wafer W from the FOUP 20 mounted on the load port 21 and transferring a wafer subjected to predetermined processing in the wafer processing unit 11 to the FOUP 20; and load-lock modules 23a and 23b as load-lock chambers for temporarily storing wafers W to be transferred between the loader module 22 and a transfer module 30 to be described later.

The FOUP 20 stores a plurality of wafers W at multiple stages spaced apart from each other at a regular interval. Generally, the FOUP 20 mounted on the load port 21 is filled with the atmosphere. However, the FOUP 20 may be filled with nitrogen gas or the like and sealed.

The loader module 22 has a rectangular inner housing, and the inside of the housing is maintained in an atmospheric pressure atmosphere. A plurality of, e.g., three load ports 21 are arranged along one long side of the housing of the loader module 22. A transfer arm (not shown) capable of moving in a longitudinal direction of the housing of the loader module 22 is provided in the housing. The transfer arm transfers a wafer W from the FOUP 20 mounted on the load port 21 to the load-lock module 23a and transfers a wafer W from the load-lock module 23b to the FOUP 20.

The load-lock module 23a temporarily holds the wafers W accommodated in the FOUP 20 mounted on the load port 21 in an atmospheric pressure atmosphere in order to transfer the wafers W to the transfer module 30 in a depressurized atmosphere which will be described later. The load-lock module 23a has an upper stocker 24a and a lower stocker 24b which hold two wafers W in an overlapped state.

The load-lock module 23a is connected to the loader module 22 through a gate 25b provided with a gate valve 25a. The gate valve 25a ensures airtightness between the load-lock module 23a and the loader module 22 and allows communication therebetween. Further, the load-lock module 23a is connected to a transfer module 30 to be described later through a gate 26b provided with a gate valve 26a. The gate valve 26a ensures airtightness between the load-lock module 23a and the transfer module 30 and allows communication therebetween.

A gas supply unit (not shown) for supplying a gas and a gas exhaust unit (not shown) for exhausting a gas are connected to the load-lock module 23a. An atmosphere in the load-lock module 23a can be switched between an atmospheric pressure atmosphere and a depressurized atmosphere by the gas supply unit and the gas exhaust unit. The load-lock module 23b has the same configuration as that of the load-lock module 23a.

The wafer processing unit 11 includes a transfer module 30 serving as a transfer chamber for transferring two wafers W at the same time, a plurality of COR modules 31 for performing COR processing on the wafer W transferred from the transfer module 30, and a plurality of PHT modules 32 for performing PHT processing on the wafer W transferred from the transfer module 30. For examples, four COR modules 31 and two PHT modules 32 are provided for the transfer module 30. The inside of the transfer module 30, the inside of the COR modules 31, and the inside of the PHT modules 32 are maintained in a depressurized atmosphere.

Two stages 33a and 33b for mounting thereon two wafers W in a horizontal direction are provided in each of the COR modules 31. The COR module 31 performs COR processing on the two wafers W mounted on the stages 33a and 33b at the same time. A gas supply unit (not shown) for supplying a processing gas, a purge gas, or the like, and a gas exhaust unit (not shown) for exhausting a gas are connected to the COR module 31.

Two stages 34a and 34b for mounting thereon two wafers W in a horizontal direction are provided in each of the PHT modules 32. The PHT module 32 performs PHT processing on the two wafers W mounted on the stages 34a and 34b at the same time. A gas supply unit (not shown) for supplying a gas and a gas exhaust unit (not shown) for exhausting a gas are connected to the PHT module 32.

The transfer module 30 transfers an unprocessed wafer W from the wafer storage unit 10 to the COR module 31 and then to the PHT module 32, and unloads a processed wafer W from the PHT module 32 to the wafer storage unit 10. The transfer module 30 has a rectangular inner housing. The inside of the housing is maintained in a depressurized atmosphere.

A wafer transfer unit 40 for transferring a wafer W is provided in the transfer module 30. The wafer transfer unit 40 includes transfer arms 41a and 41b for holding and moving two wafers W in an overlapped state, a turntable 42 for rotatably supporting the transfer arms 41a and 41b, a rotation table 43 on which the turntable 42 is mounted. A guide rail 44 extending in a longitudinal direction of the transfer module 30 is provided in the transfer module 30. The rotation table 43 is provided on the guide rail 44. The wafer transfer unit 40 is movable along the guide rail 44.

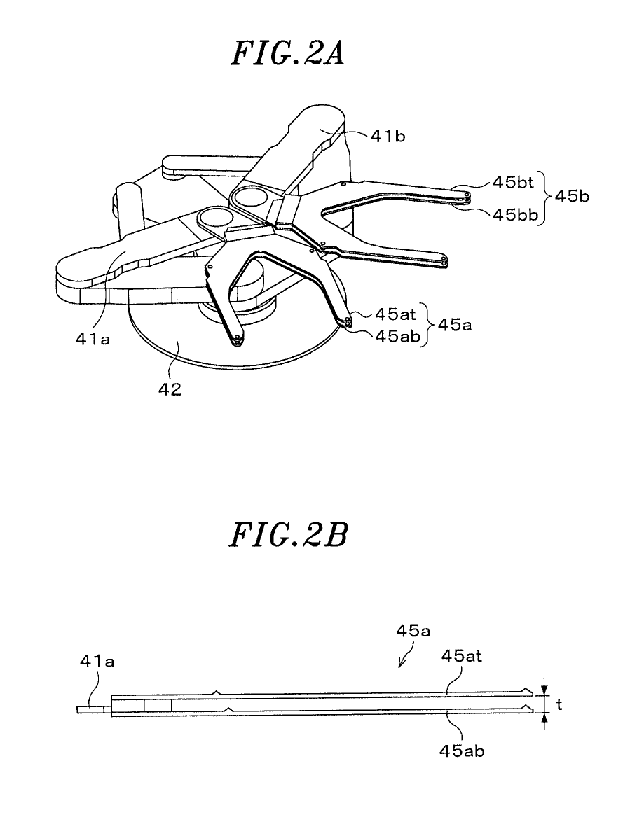

Here, the configuration of the transfer arms 41a and 41b will be described in detail. FIGS. 2A and 2B explain the configuration of the transfer arms 41a and 41b. FIG. 2A is a perspective view showing the entire transfer arms 41a and 41b. FIG. 2B is a side view of a pick unit 45a of the transfer arm 41a.

As shown in FIG. 2A, the transfer arms 41a and 41b respectively have, at leading ends thereof, pick units 45a and 45b for mounting thereon two wafers W. The transfer arm 41a has a link mechanism in which a plurality of links (nodes) is rotatably connected by a plurality of joints. One end of the link mechanism of the transfer arm 41a is rotatably supported by the turntable 42. The other end of the link mechanism of the transfer arm 41a is a free end where the pick unit 45a is provided.

The pick unit 45a has a structure in which bifurcated fork-shaped upper pick 45at and lower pick 45ab are laminated while being spaced apart from each other by a predetermined distance t. In the pick unit 45a, one wafer W is mounted on an upper surface of the upper pick 45at, and one wafer W is mounted on an upper surface of the lower pick 45ab (between the upper pick 45at and the lower pick 45ab). In other words, the transfer arm 41a allows two wafers W to be held in an overlapped state with a gap therebetween by the pick unit 45a.

By the rotation of one end of the link mechanism and the movement of the other end by the link mechanism, the transfer arm 41a moves the wafers W mounted on the pick unit 45a at the other end to a desired position. The transfer arm 41b has the same configuration as that of the transfer arm 41a. Since each of the transfer arms 41a and 41b mounts thereon two wafers W at a time, the wafer transfer unit 40 can transfer four wafers W at the same time by using the transfer arms 41a and 41b.

As shown in FIG. 1, the load-lock modules 23a and 23b are connected to the transfer module 30 through gate valves 26a as described above. Each of the COR modules 31 is connected to the transfer module 30 through a gate 46b provided with a gate valve 46a. The gate valve 46a ensures airtightness between the transfer module 30 and the COR module 31 and allows communication therebetween. Each of the PHT modules 32 is connected to the transfer module 30 through a gate 47b provided with a gate valve 47a. The gate valve 47a ensures airtightness between the transfer module and the PHT module 32 and allows communication therebetween.

The two wafers W held in an overlapped state by the upper stocker 24a and the lower stocker 24b in the load-lock module 23a are received in an overlapped state by the transfer arm 41a in the transfer module 30 and then transferred to the COR module 31 and the PHT module 32. Two wafers W processed in the PHT module 32 are held in an overlapped state by the transfer arm 41b and then transferred to the load-lock module 23b.

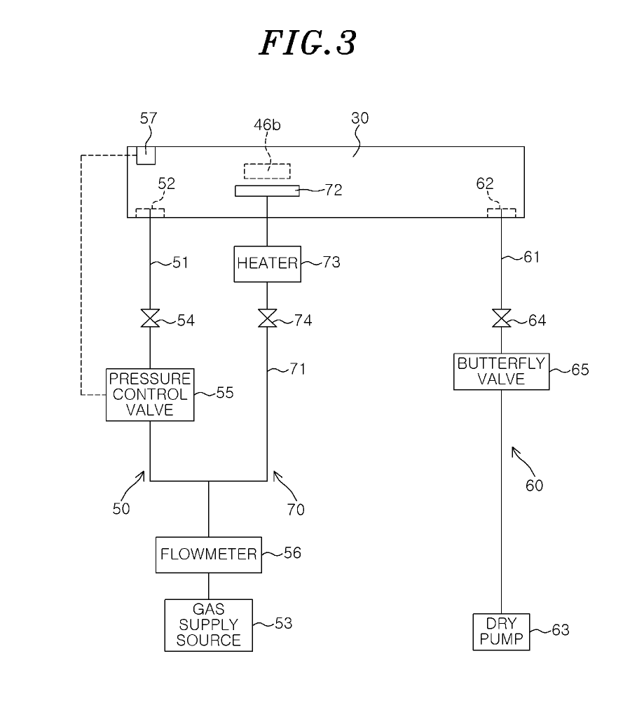

As described above, the inside of the transfer module 30 is maintained in a depressurized atmosphere. Here, the control of an atmosphere in the transfer module 30 will be described in detail. FIG. 3 is an explanatory view schematically showing a configuration of a gas supply unit and a gas exhaust unit provided in the transfer module 30.

As shown in FIG. 3, a first gas supply unit 50 for supplying an inert gas into the transfer module 30 is provided in the transfer module 30. The first gas supply unit 50 has a first gas supply line 51 (gas supply pipe). One end portion of the first gas supply line 51 communicates with a gas supply port 52 opened at one end portion of a bottom surface of the transfer module 30. The other end portion of the first gas supply line 51 communicates with a gas supply source 53 storing an inert gas, e.g., nitrogen gas. An on-off valve 54, a pressure control valve 55 (PCV), and a flowmeter 56 are provided in the first gas supply line 51 in that order from the gas supply port 52 side toward the gas supply source 53. The pressure control valve 55 is connected to a pressure gauge 57 for measuring a pressure in the transfer module 30 and controls a pressure of the inert gas based on the measurement result of the pressure gauge 57.

A gas exhaust unit 60 for exhausting an atmosphere in the transfer module 30 is provided in the transfer module 30. The gas exhaust unit 60 has a gas exhaust line 61 (gas exhaust pipe). One end portion of the gas exhaust line 61 communicates with a gas exhaust port 62 that opens at the other end portion of the bottom surface of the transfer module 30. In other words, the gas supply port 52 and the gas exhaust port 62 are arranged to face each other. The other end portion of the gas exhaust line 61 communicates with a dry pump 63 for evacuating the inside of the transfer module 30. An on-off valve 64 and a butterfly valve 65 are provided in the gas exhaust line 61 in that order from the gas exhaust port 62 side toward the dry pump 63.

Here, the flow rate of the inert gas varies depending on the gas exhaust performance of the dry pump 63, and the diameter and the length of the line. Therefore, a static-pressure in the transfer module 30 varies among a plurality of substrate processing apparatuses 1. In the present embodiment, by providing a butterfly valve 65, the difference between the apparatuses can be reduced and the flow rate of the inert gas at a static-pressure can be fixed. Accordingly, it is possible to realize the transfer module 30 that does not depend on the exhaust performance of the dry pump 63, and the diameter and the length of the line.

A second gas supply unit 70 for supplying an inert gas to the gate 46b is provided to the gate 46b disposed between the transfer module 30 and the COR module 31. The second gas supply unit 70 has a second gas supply line 71 (gas supply pipe). One end portion of the second gas supply line 71 communicates with a nozzle 72. A plurality of inert gas supply ports (not shown) is formed at the nozzle 72. The nozzle 72 is provided, e.g., below the gate 46b, and supplies an inert gas to cover the gate 46b. The other end portion of the second gas supply line 71 communicates with the gas supply source 53. In other words, the gas supply source 53 is shared by the first gas supply unit 50 and the second gas supply unit 70. A heater 73, an on/off valve 74, and a flowmeter 56 are provided in the second gas supply line 71 in that order from the nozzle 72 side toward the gas supply source 53. Then, an inert gas heated by the heater 73 is supplied from the second gas supply unit 70 to the gate 46b, and a curtain of the inert gas is formed to cover the gate 46b. In the illustrated example, the second gas supply unit 70 is provided for one gate 46b. However, the second gas supply unit 70 is also provided for the other three gates 46b.

As shown in FIG. 1, the substrate processing apparatus 1 includes a control unit 80. The control unit 80 is, e.g., a computer, and has a program storage unit (not shown). The program storage unit stores a program for controlling processing of the wafer W in the substrate processing apparatus 1. The program storage unit also stores a program for realizing a developing process in the substrate processing apparatus 1 which will be described later by controlling an operation of a driving system such as the above-described various processing devices, transfer devices and the like. The program is stored in a computer-readable storage medium, e.g., a computer-readable hard disk (HD), a flexible disk (FD), a compact disk (CD), a magnet optical disk (MO), a memory card and the like, and may be installed in the control unit 80 from the storage medium.

The substrate processing apparatus 1 of the present embodiment is configured as described above. Next, wafer processing in the substrate processing apparatus 1 will be described.

First, the FOUP 20 accommodating a plurality of wafers W is mounted on the load port 21. Then, two wafers W are transferred from the FOUP 20 to the load-lock module 23a by the loader module 22. When the wafers W are loaded into the load-lock module 23a, the gate valve 25a is closed, and the load-lock module 23a is sealed and depressurized. Next, the gate valve 26a is opened, and the inside of the load-lock module 23a and the inside of the transfer module 30 communicate with each other.

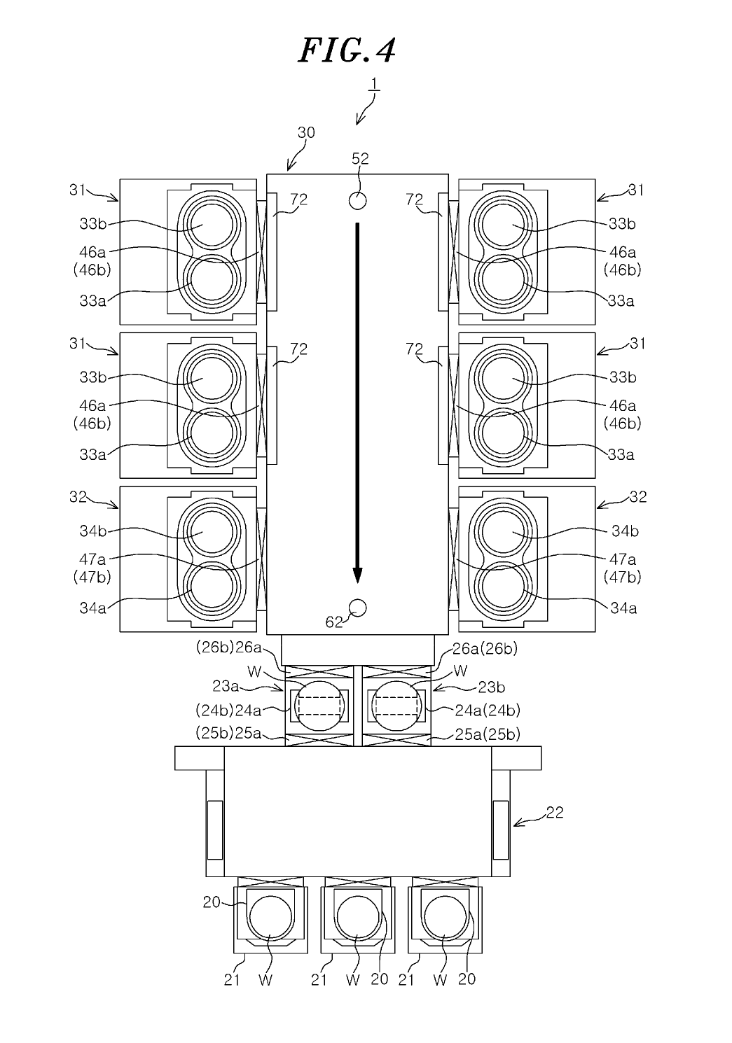

At this time, in the transfer module 30, an inert gas is supplied from the gas supply port 52 of the first gas supply unit 50, and an atmosphere is exhausted through the gas exhaust port 62 of the gas exhaust unit 60, as can be seen from FIG. 4. The inside of the transfer module 30 is maintained in a depressurized atmosphere of a predetermined pressure. A pressure in the transfer module 30 is higher than that in each of the COR modules 31 and the PHT modules 32. The pressure in the transfer module 30 is a positive pressure. In the transfer module 30, unidirectional flow of an inert gas directed from the gas supply port 52 toward the gas exhaust port 62 (indicated by an arrow in FIG. 4) is generated. Due to the unidirectional flow of the inert gas, contaminants, particles and the like in the transfer module 30 are appropriately discharged, and an atmosphere in the transfer module 30 is maintained in a clean state.

Next, when the inside of the load-lock module 23a and the inside of the transfer module 30 communicate with each other, two wafers W held in an overlapped state by the transfer arm 41a of the wafer transfer unit 40 are transferred from the load-lock module 23a to the transfer module 30. Then, the wafer transfer unit 40 moves to the front of one of the COR modules 31.

Next, the gate valve 46a is opened, and the transfer arm 41a holding the two wafers W enters the COR module 31. Then, the wafers W are transferred from the transfer arm 41a to the stages 33a and 33b. Thereafter, the transfer arm 41a retreats from the COR module 31.

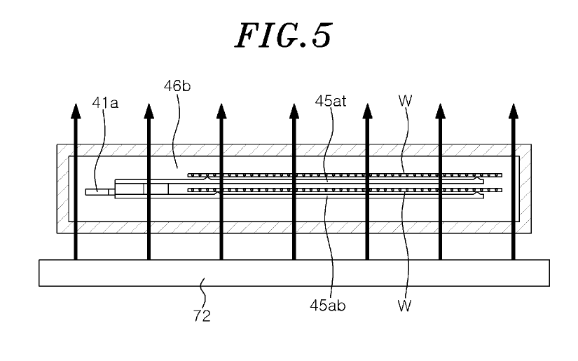

At this time, as shown in FIG. 5, an inert gas is supplied from the nozzle 72 of the second gas supply unit 70 to the gate 46b, and a curtain of the inert gas (indicated by arrows in FIG. 5) is formed. The inert gas is heated to 120° C. to 300° C. by the heater 73. The transfer arm 41a holding the two wafers W passes through the curtain of the heated inert gas. Here, deposits such as organic products are generated by the COR processing in the COR module 31. Since, however, the transfer arm 41a passes through the curtain of the heated inert gas, it is possible to suppress adhesion of the deposits onto the transfer arm 41a and the wafer W. Accordingly, even if the transfer arm 41a retreats from the COR module 31, it is possible to suppress inflow of the deposits into the transfer module 30.

When the gate valve 46a is opened to load the wafer W into the COR module 31, an atmosphere flows from the transfer module 30 to the COR module 31. This is because a pressure in the transfer module 30 is higher than that in the COR module 31. At this time, the pressure in the transfer module 30 is further decreased and, thus, the pressure of the inert gas is controlled to a predetermined level by the pressure control valve 55 in the first gas supply unit 50. When the pressure in the transfer module 30 becomes equal to that in the COR module 31, an atmosphere does not flow toward the COR module 31.

Next, when the transfer arm 41a retreats from the COR module 31, the gate valve 46a is closed and the COR processing is performed on the two wafers W in the COR module 31. When the gate valve 46a is closed, the supply of the inert gas from the second gas supply unit 70 is also stopped.

Then, when the COR processing in the COR module 31 is completed, the gate valve 46a is opened and the transfer arm 41a enters the COR module 31. Thereafter, the two wafers W are transferred from the stages 33a and 33b to the transfer arm 41a and held in an overlapped state by the transfer arm 41a. Next, the transfer arm 41a retreats from the COR module 31, and the gate valve 46a is closed.

At this time, the inert gas heated by the nozzle 72 of the second gas supply unit 70 is supplied again to the gate 46b, and a curtain of the inert gas is formed to cover the gate 46b. Then, the transfer arm 41a holding the two wafers W passes through the curtain of the heated inert gas. Here, the COR processing is performed under a depressurized atmosphere and, thus, the wafer W subjected to the COR processing is cooled. Generally, deposits tend to be adhered to a cooled object. In the present embodiment, since the transfer arm 41a passes through the heated inert gas curtain, the adhesion of deposits onto the transfer arm 41a and the wafer W can be suppressed. Accordingly, even if the transfer arm 41a retreats from the COR module 31, it is possible to suppress inflow of the deposits into the transfer module 30.

In the transfer module 30, the supply of the inert gas by the first gas supply unit 50 and the evacuation by the gas exhaust unit 60 are continuously performed during the COR processing and the loading/unloading of the wafer W into/from the COR module 31.

Next, the wafer transfer unit 40 moves to the front of one of the PHT modules 32. Then, the gate valve 47a is opened, and the transfer arm 41a holding the two wafers W enters the PHT module 32. Thereafter, the wafers W are transferred from the transfer arm 41a onto the stages 34a and 34b. Then, the transfer arm 41a retreats from the PHT module 32. Next, the gate valve 47a is closed, and PHT processing is performed on the two wafers W.

When the PHT processing is completed, the gate valve 47a is opened and the transfer arm 41b enters the PHT module 32. Then, two wafers W are transferred from the stages 34a and 34b to the transfer arm 41b and held in an overlapped manner by the transfer arm 41b. Thereafter, the transfer arm 41b retreats from the PHT module 32, and the gate valve 47a is closed.

In the transfer module 30, the supply of the inert gas by the first gas supply unit 50 and the evacuation by the gas exhaust unit 60 are continuously performed during the PHT processing and the loading/unloading of the wafer W into/from the PHT module 32.

Thereafter, the gate valve 26a is opened, and the two wafers W are loaded into the load-lock module 23b by the wafer transfer unit 40. When the wafers W are loaded into the load-lock module 23b, the gate valve 26a is closed and the load-lock module 23b is sealed and exposed to the atmosphere. Then, the two wafers W are accommodated in the FOUP 20 by the loader module 22. In this manner, a series of wafer processing in the substrate processing apparatus 1 is completed.

In accordance with the above-described embodiment, in the transfer module 30, the inert gas is supplied from the first gas supply unit 50 and exhausted through the gas exhaust unit 60 during the processing of the wafer W in the COR module 31 and the PHT module 32 and the loading/unloading of the wafer W into/from the COR module 31 and the PHT module 32. Accordingly, contaminants, particles and the like can be removed, and an atmosphere in the transfer module 30 can be maintained in a clean state.

In the case of transferring the wafer W between the COR module 31 and the transfer module 30, the heated inert gas is supplied from the second gas supply unit 70 to the gate 47b, thereby generating a curtain of the inert gas at the gate 47b. In that case, since the wafer W that is being transferred and the transfer arm 41a pass through the curtain of the inert gas, deposits generated in the COR module 31 are difficult to be adhered to the wafer W or the transfer arm 41a. Since the curtain of the inert gas is formed to cover the gate 46b, the effect of suppressing adhesion of deposits can be obtained even when the transfer arm 41a has the upper and the lower pick 45at and 45ab. Accordingly, it is possible to reduce the deposits introduced into the transfer module 30 from the COR module 31.

Here, in the COR processing in the COR module 31, deposits are generated from the stages 33a and 33b. Since the transfer arm 41a has the upper pick 45at and the lower pick 45ab, the deposits are easily adhered to the rear surface of the lower pick 45ab positioned closer to the stages 44a and 33b, compared to the upper pick 45at. Therefore, in the present embodiment, the nozzle 72 is provided below the gate 46b and a curtain of the inert gas is formed upward from a position below the gate 46b, as can be seen from FIG. 5. In that case, the inert gas is directly injected onto the rear surface of the lower pick 45ab. Therefore, it is possible to further appropriately suppress adhesion of deposits onto the rear surface of the lower pick 45ab.

In the substrate processing apparatus 1 of the above-described embodiment, the nozzle 72 of the second gas supply unit 70 is provided below the gate 46b. However, the position of the nozzle 70 is not limited thereto as long as the inert gas supplied from the nozzle 72 can cover the gate 46b. For example, the nozzle 72 may be provided above the gate 46b. In that case, an inert gas may be supplied from a position above the gate 46b. Alternatively, the nozzle 72 may be provided above and below the gate 46b. In that case, an inert gas may be supplied from positions above and below the gate 46b. Alternatively, the nozzle 72 may be provided at a side of the gate 46b. In that case, an inert gas may be supplied from the side of the gate 46b.

In the substrate processing apparatus 1 of the above-described embodiment, the inert gas supplied from the second gas supply unit 70 is heated by the heater 73. However, it is not necessary to heat the inert gas. The effect of reducing deposits can also be realized by supplying an inert gas of a room temperature from the second gas supply unit 70. However, the above effect is more intense in the case of supplying the heated inert gas. In the case of supplying the heated inert gas, it is more difficult for deposits to be adhered to the wafer W.

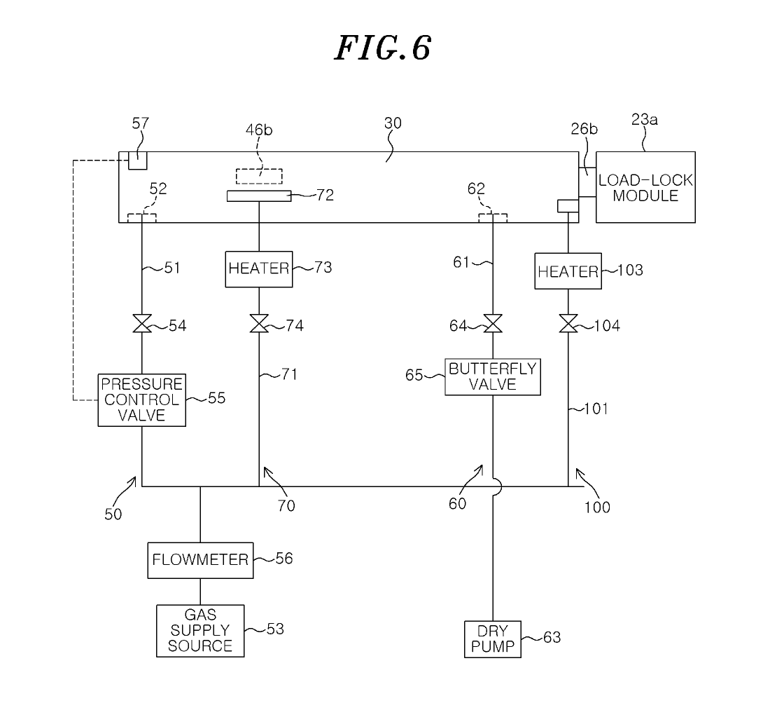

In the substrate processing apparatus 1 of the above-described embodiment, the gate 26b disposed between the transfer module 30 and the load-lock module 23a is provided with a third gas supply unit 100 for supplying an inert gas to the gate 26b, as can be seen from FIG. 6. The third gas supply unit 100 has the same configuration as that of the second gas supply unit 70. In other words, the third gas supply unit 100 has a third gas supply line 101 (gas supply pipe). One end portion of the third gas supply line 101 communicates with a nozzle 102. A plurality of inert gas supply ports (not shown) is formed at the nozzle 102. The nozzle 102 is provided, e.g., below the gate 26b, and supplies an inert gas to cover the gate 26b. The other end portion of the third gas supply line 101 communicates with the gas supply source 53. In other words, the gas supply source 53 is shared by the first gas supply unit 50, the second gas supply unit 70, and the third gas supply unit 100. A heater 103, an on/off valve 104, and a flowmeter 56 are provided in the third gas supply line 101 in that order from the nozzle 102 side toward the gas supply source 53. In the illustrated example, the third gas supply unit 100 is provided for one gate 26b. However, the third gas supply unit 100 is also provided for the other second gate 26b.

In that case, when the wafer W is transferred between the load-lock module 23a and the transfer module 30, the inert gas heated by the heater 103 is supplied from the third gas supply unit 100 to the gate 26b and a curtain of the inert gas is formed to cover the gate 26b. Then, the transfer arm 41a passes through the curtain of the heated inert gas. Here, an atmosphere in the load-lock module 23a can be switched between an atmospheric pressure atmosphere and a depressurized atmosphere, and the wafer W is held even under the depressurized atmosphere. In that case, the wafer W is cooled and, thus, particles and the like are easily adhered thereto. In the present embodiment, since the transfer arm 41a passes through the heated inert gas curtain, it is possible to suppress adhesion of particles and the like to the transfer arm 41a and the wafer W. Accordingly, it is possible to suppress inflow of the particles and the like into the transfer module 30.

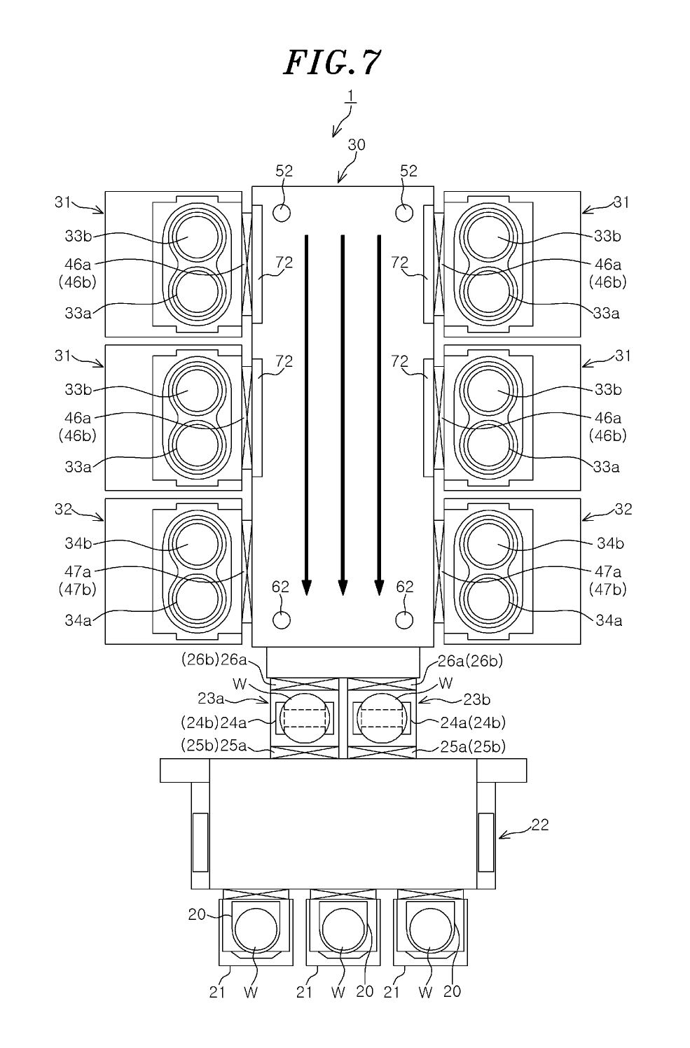

In the substrate processing apparatus 1 of the above-described embodiment, the gas supply port 52 of the first gas supply unit 50 is provided at one end of the transfer module 30, and the gas exhaust port 62 of the gas exhaust unit 60 is provided at the other end of the transfer module 30. However, the arrangement of the gas supply port 52 and the gas exhaust port 62 is not limited thereto. For example, the gas exhaust port 62 may be provided at one end portion of the transfer module 30, and the gas supply port 52 may be provided at the other end portion of the transfer module 30. Alternatively, as shown in FIG. 7, a plurality of, e.g., two gas supply ports 52 may be provided at one end portion of the transfer module 30, and a plurality of, e.g., two gas exhaust ports 62 may be provided at the other end portion of the transfer module 30.

In the substrate processing apparatus 1 of the above-described embodiment, the flowmeter 56 may have a mass flow controller (MFC) in the first gas supply unit 50. In the gas exhaust unit 60, an automatic pressure control valve (APC) may be provided instead of the butterfly valve 65. In that case, it is possible to automatically control a gas supply system and a gas exhaust system, and also possible to more precisely control an atmosphere.

In the substrate processing apparatus 1 of the above-described embodiment, a heater (not shown) may be provided in the first gas supply line 51 of the first gas supply unit 50, and the inert gas supplied from the first gas supply unit 50 may be heated. The inert gas is heated to, e.g., 120° C. to 300° C. In that case, it is possible to more appropriately suppress adhesion of contaminants or particles to the wafer W and various components in the transfer module 30. In the case of heating the inside of the transfer module 30, a heater (not shown) may be provided at the housing of the transfer module 30 to heat the entire inside of the transfer module 30.

In accordance with the present disclosure, it is possible to reduce foreign substances (deposits) introduced into the transfer chamber from the processing chamber while maintaining an atmosphere in the transfer chamber in a clean state. As a result, the reliability of the substrate processing can be improved, and the yield of the product can be improved.

In the above-described embodiment, the COR processing and the PHT processing are performed in the substrate processing apparatus 1. However, the present disclosure may also be applied to the case of performing another processing. The present disclosure is useful for processing performed in a depressurized atmosphere, such as film formation, etching or the like.

While embodiments have been described with reference to the accompanying drawings, the present disclosure is not limited to the embodiments. It is obvious to those skilled in the art that various changes or modifications can be made within the scope of the claims and such changes or modifications fall within the technical scope of the present disclosure.

What is claimed is:

1. A substrate processing apparatus comprising:
a processing chamber in which a substrate is processed in a depressurized atmosphere;
a transfer chamber connected to the processing chamber through a gate;
a first gas supply unit configured to supply an inert gas into the transfer chamber;
a second gas supply unit configured to supply an inert gas to the gate; and
a gas exhaust unit configured to exhaust an atmosphere in the transfer chamber.

2. The substrate processing apparatus of claim 1, wherein the inert gas supplied from the second gas supply unit is heated.

3. The substrate processing apparatus of claim 1, further comprising:
a load-lock chamber connected to the transfer chamber through another gate, an atmosphere in the load-lock chamber being switchable between an atmospheric pressure atmosphere and a depressurized atmosphere; and
a third gas supply unit configured to supply an inert gas to said another gate.

4. The substrate processing apparatus of claim 3, wherein the inert gas supplied from the third gas supply unit is heated.

5. The plasma processing apparatus of claim 1, wherein the first gas supply unit is provided at one end portion of the transfer chamber, and
the gas exhaust unit is provided at the other end of the transfer chamber.

6. The substrate processing apparatus of claim 1, wherein a transfer arm for transferring a substrate is provided in the transfer chamber, and
the transfer arm holds two substrates in an overlapped state with a gap between the two substrates.

7. A substrate processing method using a substrate processing apparatus including a processing chamber in which a substrate is processed in a depressurized atmosphere and a transfer chamber connected to the processing chamber through a gate, the method comprising:
supplying an inert gas from a first gas supply unit into the transfer chamber during the processing of the substrate in the processing chamber and transfer of the substrate between the processing chamber and the transfer chamber, and
supplying an inert gas from a second gas supply unit to the gate when the gate is opened to transfer the substrate between the processing chamber and the transfer chamber.

8. The substrate processing method of claim 7, wherein the inert gas supplied from the second gas supply unit is heated.

9. The substrate processing method of claim 7, wherein the substrate processing apparatus further includes a load-lock chamber connected to the transfer chamber through another gate, an atmosphere in the load-lock chamber being switchable between an atmospheric pressure atmosphere and a depressurized atmosphere, and
wherein the substrate processing method further comprises:
supplying an inert gas from the first gas supply unit into the transfer chamber when the substrate is accommodated in the load-lock chamber and transferred between the load-lock chamber and the transfer chamber; and
supplying an inert gas from a third gas supply unit to another gate when said another gate is opened to transfer the substrate between the load-lock chamber and the transfer chamber.

10. The substrate processing method of claim 9, wherein the inert gas supplied from the third gas supply unit is heated.

11. A computer-readable storage medium storing a program operating on a computer of a control unit for controlling a substrate processing apparatus to perform the substrate processing method described in claim 7.
